(19) United States
(12) Patent Application Publication
(10) Pub. No.: US 2012/0132283 A1
(43) Pub. Date: May 31, 2012

(54) CADMIUM TELLURIDE SOLAR CELL AND METHOD OF FABRICATING THE SAME

(75) Inventor: Bulent M. BASOL, Manhattan Beach, CA (US)

(73) Assignee: Encoresolar, Inc., Fremont, CA (US)

(21) Appl. No.: 13/305,541

(22) Filed: Nov. 28, 2011

Related U.S. Application Data
(60) Provisional application No. 61/458,594, filed on Nov. 29, 2010.

(51) Int. Cl. H01L 31/0264

(52) U.S. Cl. 136/260

(57) ABSTRACT

A thin film solar cell includes a buffer layer disposed between a transparent conductive layer and a junction partner layer. The solar cell has an absorber layer made from a Group II-VI compound which is in contact with the junction partner layer. The buffer layer is made from at least one of cadmium doped tin oxide, indium sulfide, tin doped indium sulfide, gallium sulfide and tin doped gallium sulfide.

### FIELD OF THE INVENTION

The present invention relates to methods for fabricating thin film IIB-VIA compound solar cells, more specifically CdTe solar cells.

### BACKGROUND OF THE INVENTION

Solar cells and modules are photovoltaic (PV) devices that convert sunlight energy into electrical energy. The most common solar cell material is silicon (Si). However, lower cost PV cells may be fabricated using thin film growth techniques that can deposit solar-cell-quality polycrystalline compound absorber materials on large area substrates using low-cost methods.

Group IIB-VIA compound semiconductors comprising some of the Group IIB (Zn, Cd, Hg) and Group VIA (O, S, Se, Te, Po) materials of the periodic table are excellent absorber materials for thin film solar cell structures. Especially CdTe has proved to be a material that can be used in manufacturing high efficiency solar panels at a manufacturing cost of below $1/W.

FIG. 1 shows a commonly used structure of a CdTe based thin film solar cell. FIG. 1 shows a “super-strate” structure 10, wherein light enters the active layers of the device through a transparent sheet 11. The transparent sheet 11 serves as the support on which the active layers are deposited. In fabricating the “super-strate” structure 10, a transparent conductive layer (TCL) 12 is first deposited on the transparent sheet 11. Then a junction partner layer 13 is deposited over the TCL 12. A CdTe absorber film 14, which is a p-type semiconductor film, is next formed on the junction partner layer 13. Then an ohmic contact layer 15 is deposited on the CdTe absorber film 14, completing the solar cell. As shown by arrows 18 in FIG. 1, light enters this device through the transparent sheet 11. In the “super-strate” structure 10 of FIG. 1, the transparent sheet 11 may be glass or a material (e.g., a high temperature polymer such as polyimide) that has high optical transmission (such as higher than 80%) in the visible spectra of the sun light. The TCL 12 is usually a transparent conductive oxide (TCO) layer comprising any one of; tin-oxide (SnO₂), cadmium-tin-oxide (Cd₂SnO₄), indium-tin-oxide (ITO, tin doped indium oxide, or Sn:In₂O₃), and zinc-oxide (ZnO) which are doped to increase their conductivity. Multi layers of these TCO materials as well as their alloys or mixtures may also be utilized in the TCL 12. The junction partner layer 13 is typically a CdS layer, but may alternately be compound layer such as a layer of CdZnS, ZnS, ZnSe, ZnSSe, CdZnSe, etc. The ohmic contact 15 is made of a highly conductive metal such as Mo, Ni, Cr, Ti, Al, a metal nitride or a doped transparent conductive oxide such as the TCOs mentioned above. The rectifying junction, which is the heart of this device, is located near an interface 19 between the CdTe absorber film 14 and the junction partner layer 13.

In high efficiency CdTe solar cells it is common to also employ a buffer layer (not shown in FIG. 1) sandwiched between the TCL 12 and the junction partner layer 13. The buffer layer may have a thickness in the range of 0.05-0.2 um and usually a resistivity that is much higher than the resistivity of the TCL 12. Typical materials used in the buffer layer include undoped, high resistivity tin oxide, zinc stannate or zinc tin oxide represented by the chemical formula Zn₂SnO₄, gallium oxide and indium oxide. These materials yield good results in the form of higher open circuit voltages for solar cells fabricated by vapor depositing a CdTe layer on the junction partner layer. In approaches involving electrodeposition of the CdTe film over the junction partner layer, on the other hand, such standard buffer materials introduce excessive resistance and negatively impact the CdTe deposition process due to large voltage drops, since the deposition current needs to pass through the TCL, the high resistance buffer layer and the junction partner layer. The present invention provides an alternate buffer layer with improved performance, especially for electrodeposition based CdTe solar cell fabrication.

### BRIEF DESCRIPTION OF THE DRAWINGS

FIG. 1 is a cross-sectional view of a prior-art CdTe solar cell with a “super-strate structure”.

FIG. 2 is a cross-sectional view of a thin film solar cell with an improved structure. The sequence of the layers of FIG. 2 are shown reversed in relation to the sequence shown in FIG. 1.

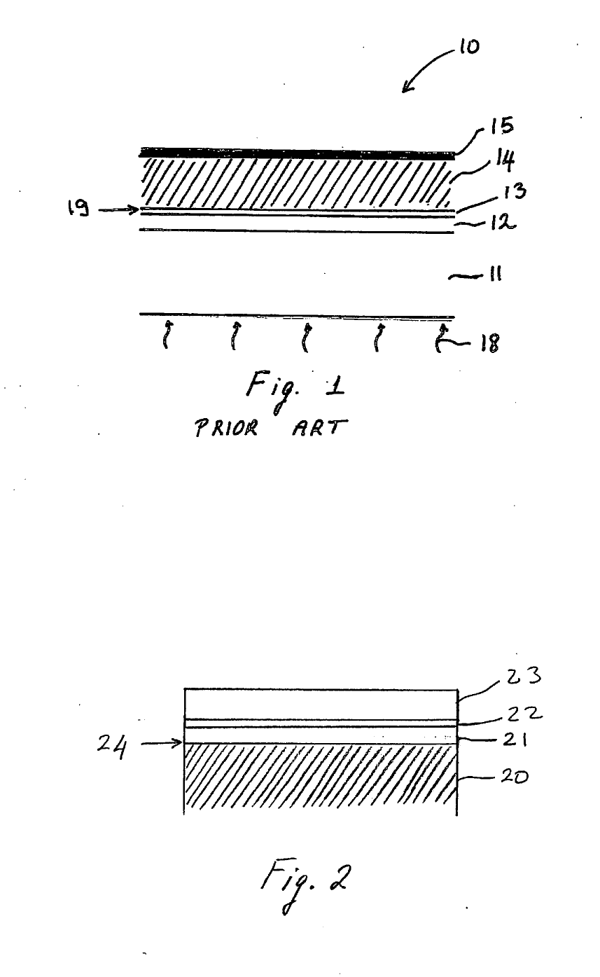

### DETAILED DESCRIPTION OF THE INVENTION

FIG. 2 shows a cross sectional view of a near-junction region of a CdTe solar cell constructed in accordance with the teachings of the present inventions. It should be noted that FIG. 2 concentrates just on the junction area of the device and does not show other parts of the solar cell such as the ohmic contact, etc.

Referring back to FIG. 2, a CdTe film 20 is in intimate contact with a junction partner film 21, forming a rectifying junction 24. A buffer film 22 is sandwiched between the junction partner film 21 and a transparent conductive film 23.

The junction partner film 21 is typically a CdS layer, but may alternately be a compound layer such as a layer of CdZnS, ZnS, ZnSe, ZnSSe, CdZnSe, etc. The transparent conductive film 23 is usually a transparent conductive oxide (TCO) layer comprising any one of; tin-oxide, cadmium-tin-oxide, indium-tin-oxide, and zinc-oxide which are doped to increase their conductivity. It should be noted that the cadmium-tin-oxide material used as a TCO layer has the chemical formula of Cd₂SnO₄ and the indium-tin-oxide typically consists of 90% indium oxide and about 10% tin oxide. The resistivity of these transparent conductive oxides with the above given compositions are much lower than 0.001 ohm-cm, preferably lower than 0.0005 ohm-cm. Multi layers of these TCO materials as well as their alloys or mixtures may also be utilized in the transparent conductive film 23.

The buffer film 22 comprises at least one of cadmium doped tin oxide, indium sulfide, gallium sulfide, indium tin sulfide (or tin doped indium sulfide) and gallium tin sulfide (or tin doped gallium sulfide). The amount of cadmium doping in tin oxide may be less than about 10 mole-percent, preferably less than about 5 mole-percent. In other words, the cadmium doped tin oxide comprises at most 10 moles of CdO and at least 90 moles of SnO₂. For indium tin sulfide and gallium tin sulfide, the tin to indium (Sn/In) and tin to gallium (Sn/Ga) molar ratios may be 0.2 or less. The doping of the indium sulfide (In₂S₃) and gallium sulfide (Ga₂S₃) materials with tin (Sn) opens up the optical bandgap of these materials to above 2.5 eV, which is wider than the bandgap of the junction partner layer (CdS) and also keeps the resistivity values in the desired range of 0.1-100 ohm-cm, which is especially preferred for the fabrication of solar cells by electrodepositing the CdTe layer.

The thickness of the buffer film 22 is in the range of 0.01-0.15 um (10-150 nm). Its resistivity is in the range of 0.1-100 ohm-cm, preferably in the range of 0.5-50 ohm-cm, most preferably in the range of 1-20 ohm-cm. The buffer film 22 may be deposited by various techniques such as physical vapor deposition, chemical vapor deposition, liquid spraying, etc. One preferred method is sputtering. The sputtering process may be carried out using compound targets; i.e. for cadmium doped tin oxide targets comprising (CdO+SnO₂) with relative amounts of oxides cited above may be used, for sulfides targets comprising gallium sulfide, indium sulfide and tin sulfide with the above cited amounts may be utilized. Alternately metallic targets comprising Cd and Sn, i.e. cadmium-tin alloy, may be used and the sputtering process may be performed in oxygen containing chambers in a reactive sputtering mode for the cadmium doped tin oxide deposition. For the deposition of sulfides in a reactive mode, a reactive gas comprising sulfur, such as H₂S, may be utilized.

Although the present invention is described with respect to certain preferred embodiments, modifications thereto will be apparent to those skilled in the art.

What is claimed is:

1. A thin film solar cell structure comprising;
a buffer layer sandwiched between a transparent conductive layer and a junction partner layer; and
a Group II-VI compound absorber layer in intimate contact with the junction partner layer;
wherein the buffer layer comprises at least one of cadmium doped tin oxide, indium sulfide, tin doped indium sulfide, gallium sulfide and tin doped gallium sulfide.

2. The structure in claim 1 wherein the Group II-VI compound is CdTe.

3. The structure in claim 2 wherein the junction partner layer comprises Cd and S.

4. The structure in claim 1 wherein the buffer layer comprises cadmium doped tin oxide with a Cd to Sn molar ratio of less than 0.1.

5. The structure in claim 1 wherein the buffer layer comprises tin doped indium sulfide with a Sn to In molar ratio of less than 0.2.

6. The structure in claim 1 wherein the buffer layer comprises tin doped gallium sulfide with a Sn to Ga molar ratio of less than 0.2.
